(19) United States
(12) Patent Application Publication
(10) Pub. No.: US 2026/0114227 A1
(43) Pub. Date: Apr. 23, 2026

(54) LOAD PORT AND TRANSPORT SYSTEM

(71) Applicant: HIRATA CORPORATION, Kumamoto-shi (JP)

(72) Inventor: Hiroki TAKAJO, Kumamoto-shi (JP)

(73) Assignee: HIRATA CORPORATION, Kumamoto-shi (JP)

(21) Appl. No.: 19/357,242

(22) Filed: Oct. 14, 2025

(30) Foreign Application Priority Data
Oct. 21, 2024 (JP) 2024-185203
Mar. 10, 2025 (JP) 2025-037685

(51) Int. Cl. H01L 21/677

(52) U.S. Cl. CPC H10P 72/3406; H10P 72/3408

(57) ABSTRACT

A load port includes a placing portion, a storage portion disposed below the placing portion, a port door, a bolts plate including an opening portion, and a lifting mechanism configured to move the port door up and down with respect to the opening portion. The lifting mechanism includes a lifting portion stored in the storage portion, a coupling member couples the lifting portion and the port door through a slit in the bolts plate, and a driving mechanism moves the lifting portion up and down between a first position and a second position. The lifting portion includes a space portion into which a driving source of the driving mechanism enters at the second position. The second position is a position at which the lifting portion overlaps the driving source in a side view, and at which the space portion overlaps the driving source in a plan view.

### CROSS-REFERENCE TO RELATED APPLICATION(S)

This application claims priority to and the benefit of Japanese Patent Application No. 2024-185203 filed on Oct. 21, 2024, and Japanese Patent Application No. 2025-037685 filed on Mar. 10, 2025, the entire disclosures of which are incorporated herein by reference.

### BACKGROUND OF THE INVENTION

### Field of the Invention The present invention relates to a load port and a transport system.

### Description of the Related Art A known container is, for example, a Front-Opening Unified Pod (FOUP) that accommodates a substrate such as a semiconductor wafer. Such a container is opened and closed in a load port included in a substrate transport apparatus, and the substrate inside the container is taken in and out. Japanese Patent Laid-Open No. 2002-184831 discloses a load port that has a port door for holding a lid portion of a container and opens and closes the container by moving the port door up and down.

The size of the container is standardized. For example, in a case of FOUP, the size is defined by SEMI standards. When the container is opened, it is necessary to completely open an opening of the container, and a lifting distance of the lid portion of the container is affected by the standard size. A lifting mechanism of the lid portion is configured to move the lid portion up and down by the lifting distance, and when the load port is downsized, the lifting distance cannot be shortened, and there are design restrictions in this respect.

### SUMMARY OF THE INVENTION

An object of the present invention is to reduce the size of a load port.

According to an aspect of the present invention, there is provided a load port comprising: a placing portion on which a container in which a substrate is accommodated is placed; a storage portion disposed below the placing portion; a port door configured to be capable of holding a door portion of the container; a bolts plate disposed between the placing portion and the storage portion, and the port door, the bolts plate including an opening portion which is openable and closable by the port door and through which the substrate is capable of being taken in and out; and a lifting mechanism configured to move the port door up and down with respect to the opening portion, wherein the lifting mechanism includes: a lifting portion stored in the storage portion; a coupling member configured to couple the lifting portion and the port door through a slit formed in the bolts plate; and a driving mechanism including a driving source stored in the storage portion and configured to move the lifting portion up and down between a first position and a second position, the lifting portion includes a space portion into which the driving source is capable of entering at the second position, and the second position is a position at which the lifting portion overlaps the driving source in a side view, and at which the space portion overlaps the driving source in a plan view.

Further features of the present invention will become apparent from the following description of exemplary embodiments (with reference to the attached drawings).

### BRIEF DESCRIPTION OF THE DRAWINGS

FIG. 1 is an external view of a transport system according to an embodiment of the present invention;

FIG. 2 is a diagram showing an internal mechanism of a load port and a substrate transport apparatus of the transport system in FIG. 1;

FIG. 3 is a plan view of a configuration around a lifting portion;

FIG. 4 is a perspective view of the configuration around the lifting portion;

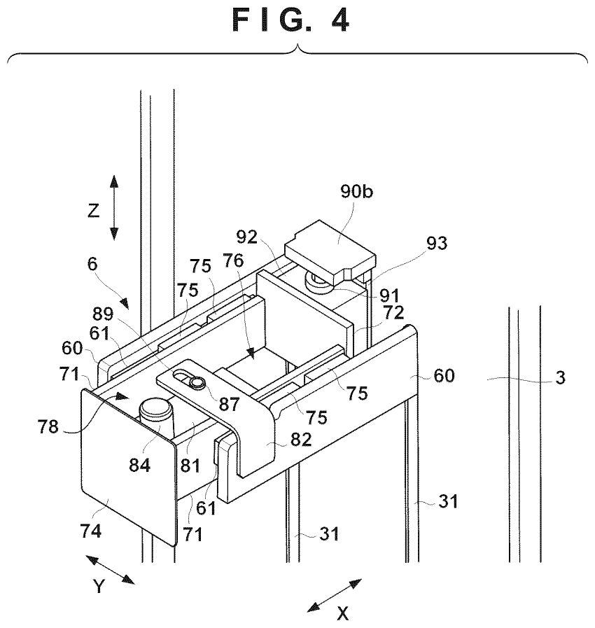

FIG. 5 is an explanatory view of an operation of the load port of FIG. 1;

FIG. 6 is an explanatory view of an operation of the load port of FIG. 1;

FIG. 7 is a partial cross-sectional view of a periphery of a P1 portion in FIG. 5 as viewed from a side;

FIG. 8 is a partial cross-sectional view of a periphery of a P2 portion in FIG. 6 as viewed from the side; and

FIG. 9 is a diagram illustrating another arrangement example of a motor.

### DESCRIPTION OF THE EMBODIMENTS

Hereinafter, embodiments will be described in detail with reference to the attached drawings. Note that the following embodiments are not intended to limit the scope of the claimed invention, and limitation is not made to an invention that requires all combinations of features described in the embodiments. Two or more of the multiple features described in the embodiments may be combined as appropriate. Furthermore, the same reference numerals are given to the same or similar configurations, and redundant description thereof is omitted.

### First Embodiment

### Outline of Apparatus

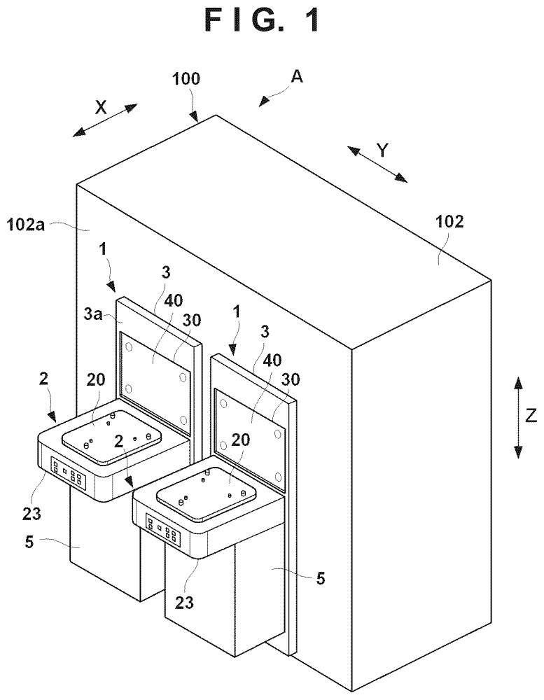

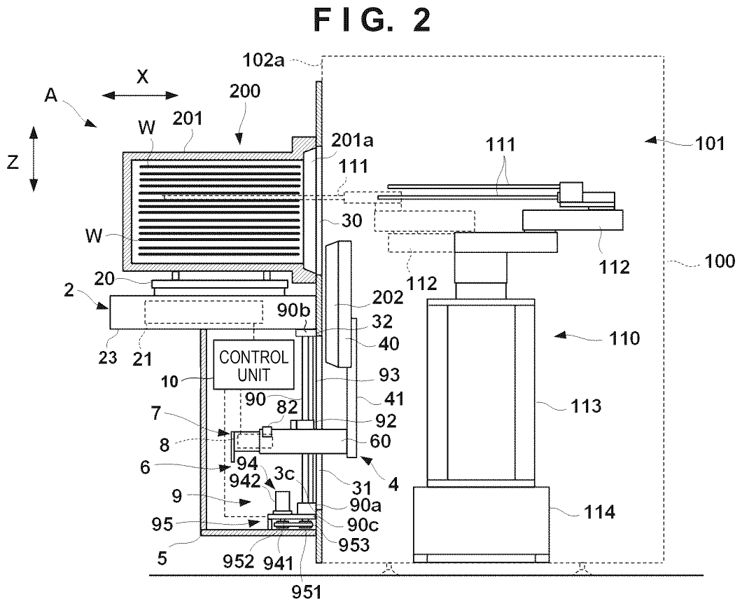

FIG. 1 is an external view of a transport system A according to an embodiment of the present invention. The transport system A includes a load port 1 and a substrate transport apparatus 100. FIG. 2 is a diagram showing an internal mechanism of the load port 1 and the substrate transport apparatus 100, and is a schematic cross-sectional view when a container 200 is placed on the load port 1. In each drawing, arrows X and Y indicate horizontal directions orthogonal to each other, and arrow Z indicates an up-down direction.

The load port 1 is a device that opens and closes the container 200 such as a FOUP. The container 200 includes: a box-shaped container main body 201 that has an opening portion 201a on a side for taking in and out a substrate W such as a semiconductor wafer; and a door portion 202 that is detachably attached to the opening portion 201a and closes the opening portion 201a, and accommodates the substrate W. Note that FIG. 2 illustrates a state in which the door portion 202 is removed from the container main body 201 by the load port 1 and the door portion 202 is being lowered.

The load port 1 is attached to the substrate transport apparatus 100 including a substrate transport robot 110 for transporting the substrate W therein. The substrate transport apparatus 100 includes a housing 102 that accommodates the substrate transport robot 110. The load port 1 is attached to a front wall 102a of the housing 102. In an example of FIG. 1, two load ports 1 are attached to the front wall 102a. The substrate transport robot 110 carries the substrate W out of and into the container 200 placed on the load port 1.

The substrate transport robot 110 includes an end effector 111 that holds the substrate W, an articulated arm 112 that holds the end effector 111 and moves at least forward and backward, and a driving unit 113 that allows the articulated arm 112 to pivot and move up and down. The substrate transport robot 110 further includes a traveling unit 114 that reciprocates the substrate transport robot 110 in a Y direction. As indicated by a broken line in FIG. 2, the end effector 111 of the substrate transport robot 110 is caused to enter the inside of the container main body 201 in which the opening portion 201a is opened to a side of the substrate transport apparatus 100, whereby the substrate W is carried out and carried in.

The load port 1 includes a placing portion 2 on which the container 200 is placed, a bolts plate 3, a port door 4, and a storage portion 5 disposed below the placing portion 2. The bolts plate 3 is a plate-shaped wall member extending in the Z direction, and includes a front surface 3a on a side of the placing portion 2 and a back surface 3b on the side of the substrate transport apparatus 100. The bolts plate 3 closes an opening portion formed in the front wall 102a to partition an external space on the side of the placing portion 2 and a transport space 101 of the substrate W in the substrate transport apparatus 100 together with the front wall 102a. In terms of the partition wall, the bolts plate 3 can also be said to be a member forming a part of the front wall 102a. The bolts plate 3 includes an opening portion 30 through which the detached door portion 202 and the end effector 111 can pass in an X direction. In addition, the bolts plate 3 includes an attachment portion 3c to which a driving mechanism 9 described later is attached at a predetermined position on the front surface 3a.

The port door 4 includes a holding portion 40 that holds the door portion 202 and a support portion 41 that supports the holding portion 40. The holding portion 40 includes, for example, a chucking mechanism, and thus it is possible to chuck and hold the door portion 202. Further, the holding portion 40 is provided with an operation mechanism (latch key) that operates opening/closing of a lock mechanism included in the door portion 202. Thus, the container main body 201 and the door portion 202 can be detached and attached.

The placing portion 2 includes a dock plate 20 on which the container 200 is placed and a housing 23 that accommodates an operation mechanism therein. The operation mechanism includes a displacement mechanism 21 that displaces the dock plate 20 in the X direction, a seat sensor that detects the presence of the container 200, a lock mechanism that locks the container 200 placed on the dock plate 20 to the dock plate 20, and the like. The dock plate 20 is provided with a plurality of positioning pins (kinematic pins) that supports the container 200 while positioning it. The housing 23 is a rectangular parallelepiped-shaped hollow body.

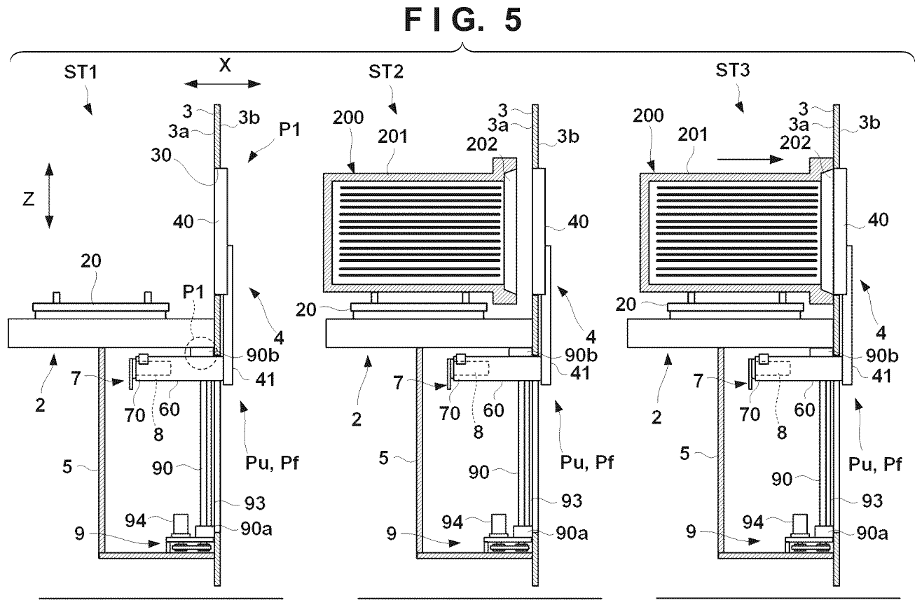

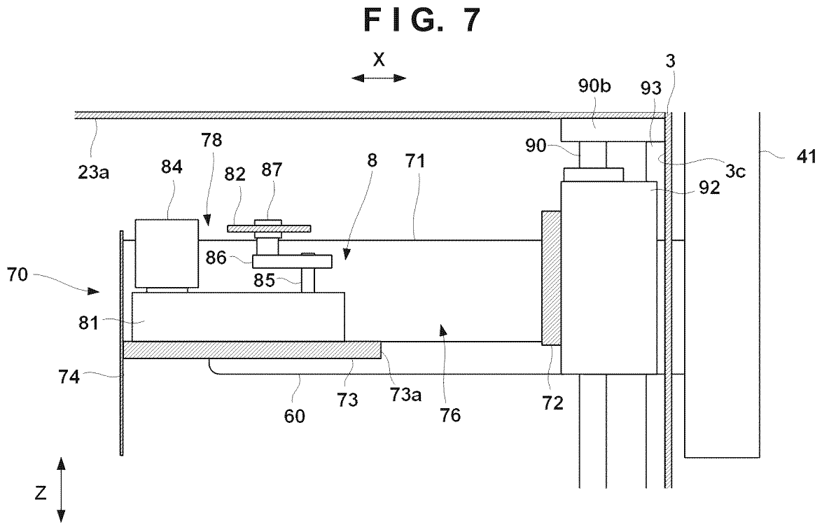

Reference is made to FIG. 7 in addition to FIG. 1. FIG. 7 is a partial cross-sectional view illustrating a periphery of a P1 portion in FIG. 5 to be described later. The housing 23 includes a bottom plate 23a. The displacement mechanism 21 is provided on the bottom plate 23a.

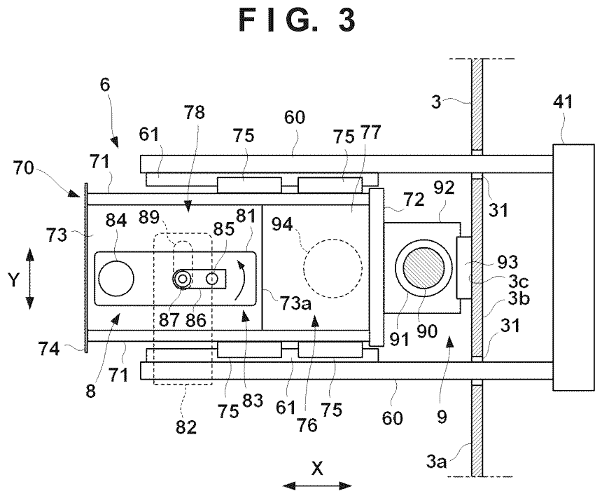

The storage portion 5 is a rectangular parallelepiped-shaped hollow body. The storage portion 5 is provided with a lifting mechanism 6 that moves the port door 4 up and down with respect to the opening portion 30. The lifting mechanism 6 includes a lifting portion 7 stored in the storage portion 5, a pair of coupling members 60 coupling the lifting portion 7 and the port door 4, and the driving mechanism 9. Reference is made to FIG. 3 in addition to FIG. 2. FIG. 3 is a plan view of a configuration around the lifting portion 7.

In a case of the present embodiment, the driving mechanism 9 is a ball screw mechanism. However, another driving mechanism may be used. The driving mechanism 9 includes a ball screw shaft 90, a slider 92, a guide member 93, a motor 94 as a driving source, and a belt transmission mechanism 95. The guide member 93 is a rail member that guides movement of the slider 92 in the up-and-down direction, and is fixed to the front surface 3a of the bolts plate 3.

The guide member 93 extends in the Z direction, and is attached to the attachment portion 3c provided on the bolts plate 3 such that a lower end thereof is located in a lower portion of the storage portion 5 and an upper end thereof is located below the placing portion 2. The slider 92 has an engaging portion that engages with the guide member 93, and can reciprocate in the Z direction by the guide of the guide member 93. The slider 92 is provided with a ball nut 91 that engages with the ball screw shaft 90 via a ball. The slider 92 moves along the ball screw shaft 90 and the guide member 93.

The ball screw shaft 90 extends in the Z direction, and a lower end thereof is rotatably supported by a shaft support member 90a disposed in the lower portion of the storage portion 5, and an upper end thereof is rotatably supported by a shaft support member 90b disposed below the placing portion 2.

The shaft support member 90b is attached to the attachment portion 3c provided on the bolts plate 3. Further, an attachment member 90c is attached to the shaft support member 90a. The shaft support member 90a and the attachment member 90c are attached to the attachment portion 3c provided on the bolts plate 3. The shaft support member 90a and the attachment member 90c are located in the lower ends of the ball screw shaft 90 and the guide member 93. The ball screw shaft 90 is connected to the belt transmission mechanism 95 on a lower end side. The attachment member 90c is a plate-like member fixed to the shaft support member 90a and extending in the X direction, the motor 94 is mounted on an upper surface, and the belt transmission mechanism 95 is supported on a lower surface.

The belt transmission mechanism 95 includes a driven pulley 951 connected to the ball screw shaft 90, a drive pulley 952 connected to an output shaft of the motor 94, and an endless belt 953 wound around these pulleys. The motor 94 includes an output shaft 941 and a driving portion 942 that rotationally drives the output shaft 941. The motor 94 is disposed in the storage portion 5 at the height of the lower end of the guide member 93 in a posture in which the output shaft 941 is directed downward. Rotational force of the motor 94 is transmitted to the ball screw shaft 90 via the belt transmission mechanism 95, and the ball screw shaft 90 rotates. The slider 92 provided with the ball nut 91 moves up and down by the rotation of the ball screw shaft 90.

The pair of coupling members 60 is a plate-shaped member, and extends in the X direction through a pair of slits 31 formed in the bolts plate 3. One end of each coupling member 60 is located in the storage portion 5, and another end thereof is located in the transport space 101. Each slit 31 extends in the Z direction and is an opening penetrating the bolts plate 3, and the pair of slits 31 is separated in the Y direction. The support portion 41 of the port door 4 is fixed to the ends of the pair of coupling members 60 in the X direction.

The lifting portion 7 includes a support member 70 and an advancing and retreating mechanism 8. The support member 70 is a frame member including a pair of side plates 71 separated in the Y direction, an end plate 72 on a side of the bolts plate 3 coupling the pair of side plates 71, a bottom plate 73 coupling the pair of side plates 71, and an end plate 74 on a side opposite to the bolts plate 3 coupling the pair of side plates 71. The end plate 72 is fixed to the slider 92, and the lifting portion 7 is lifted and lowered by moving the slider 92 up and down.

The support member 70 forms a space portion 76 described later. The space portion 76 is a space surrounded by the plates constituting the support member 70.

The lifting portion 7 has an internal space surrounded by the pair of side plates 71, the end plate 72, and the end plate 74. The internal space includes a mechanism arrangement portion 78 in which the advancing and retreating mechanism 8 is arranged and the space portion 76 which is a gap. The space portion 76 is arranged closer to the bolts plate 3 than the mechanism arrangement portion 78.

An opening portion 77 is formed to be separated from an end 73a of the bottom plate 73 and the end plate 72. A space above the opening portion 77 is formed as the space portion 76 surrounded by the pair of side plates 71 and the end plate 72. The space portion 76 is located at a position overlapping with the motor 94 in the Z direction, that is, at a position overlapping with the motor in a plan view, and is a space into which at least a part of the motor 94 can enter when the lifting portion 7 descends as described later. In the case of the present embodiment, a part of the motor 94 on a side opposite to the output shaft is configured to be able to enter the space portion 76.

The coupling member 60 is supported on each side plate 71 so as to be slidable in the X direction. A rail member 61 is fixed to the coupling member 60, and a plurality of sliders 75 is fixed to the side plate 71. The plurality of sliders 75 engages with the rail member 61 extending in the X direction, and these constitute a linear guide. The rail member 61 can reciprocate in the X direction by the guide of the sliders 75. The coupling member 60 is disposed on a side of the side plate 71 so as to overlap the side plate 71 in a side view in the Y direction.

The advancing and retreating mechanism 8 is a mechanism that advances and retreats the port door 4 in an advance and retreat direction (X direction in the present embodiment) with respect to the opening portion 30, and is supported by the support member 70. The advancing and retreating mechanism 8 of the present embodiment is a cam mechanism that is provided on the bottom plate 73 and moves the pair of coupling members 60 in the X direction. The advancing and retreating mechanism 8 and the space portion 76 are arranged side by side in the horizontal direction (X direction), and the space portion 76 is positioned between the advancing and retreating mechanism 8 and the end plate 72 or the slider 92. A compact layout is possible while preventing interference between the motor 94 accommodated in the space portion 76 and the advancing and retreating mechanism 8 due to lowering of the lifting portion 7.

The advancing and retreating mechanism 8 includes a transmission unit 81, a cam member 82, a motor 84 as a driving source, a rotary shaft 85, an arm member 86, and a roller 87. The rotary shaft 85 is a shaft member extending in the Z direction, and driving force is transmitted from an output shaft of the motor 84 via the transmission unit 81 to rotate the shaft about a Z-axis. The transmission unit 81 is, for example, a unit including a belt transmission mechanism therein. The arm member 86 is fixed to the rotary shaft 85 at one end thereof, and rotation of the rotary shaft 85 causes the arm member 86 to turn about the rotary shaft 85 as a rotation center. The roller 87 rotatable about the Z-axis is supported at another end of the arm member 86. In the case of the present embodiment, a turning range of the arm member 86 is within a range of the bottom plate 73 as viewed in a Z-axis direction.

The cam member 82 is an L-shaped member, one end thereof is an L-shaped member fixed to one coupling member 60 of the pair of coupling members 60, and a cam hole 89 is formed in another end thereof. The cam hole 89 is an oval opening portion. The roller 87 is inserted into the cam hole 89, and a peripheral surface of the roller 87 is in contact with an inner surface of the cam hole 89. When the motor 84 turns the arm member 86, the roller 87 performs a circular motion about the rotary shaft 85. When the roller 87 abuts on the inner surface of the cam hole 89, the coupling member 60 is moved in the X direction while a relative position in the Y direction between the roller 87 and the cam hole 89 is changed. Thus, the port door 4 moves forward and backward in the X direction.

Referring to FIG. 2, the load port 1 is provided with a control unit 10.

The control unit 10 is an electronic circuit that controls the load port 1. The control unit 10 includes, for example, a processing unit represented by a CPU, storage units such as a RAM and a ROM, an input/output interface between an external device and the processing unit, and a communication interface that performs communication with a computer such as a host computer or a peripheral device (such as the substrate transport robot 110) via a communication line. The control unit 10 acquires, for example, detection results of various sensors and controls various driving sources. The various sensors include, for example, a seat sensor of the dock plate 20, a sensor provided in the driving mechanism 9, and a sensor provided in the advancing and retreating mechanism 8. The various driving sources include the motor 94, the motor 84, a driving source of the driving mechanism 21, a driving source of the holding portion 40, and the like.

### Example of Control

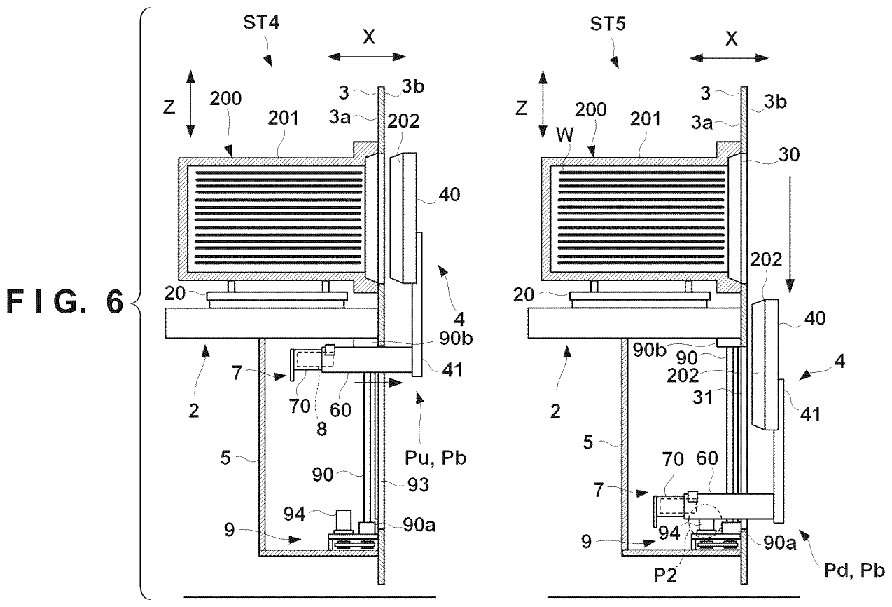

An example of control of the load port 1 by the control unit 10 will be described. FIGS. 5 and 6 illustrate an example of an operation of the load port 1 under the control of the control unit 10, and particularly illustrate an opening operation of the container 200.

Refer to FIG. 5. A state ST1 indicates a stage before the container 200 is placed on the placing portion 2. The dock plate 20 is located away from the bolts plate 3. A position of the port door 4 is an attachment and detachment position Pu and an advanced position Pf. The attachment and detachment position Pu corresponds to an upper limit position of a lifting range of the lifting portion 7.

The opening portion 30 is closed by the holding portion 40.

FIG. 7 is a partial cross-sectional view illustrating a periphery of a P1 portion in FIG. 5. The slider 92 moving along the ball screw shaft 90 and the guide member 93 is located in the vicinity of a lower side of the bottom plate 23a of the housing 23 constituting the placing portion 2.

Returning to FIG. 5, a state ST2 indicates a stage in which the container 200 is placed on the dock plate 20 of the placing portion 2. The position of the port door 4 is the same as that in the state ST1. A state ST3 shows a stage in which the dock plate 20 has advanced with respect to the bolts plate 3 and the door portion 202 of the container 200 has been connected to the holding portion 40 of the port door 4. The position of the port door 4 is the same as that in the state ST1. The door portion 202 is held by the holding portion 40 from a side of the transport space 101, and the lock of the door portion 202 with respect to the container 200 is released.

Refer to FIG. 6. A state ST4 indicates a stage in which the door portion 202 is separated from the container main body 201 of the container 200, and the container 200 is opened. The advancing and retreating mechanism 8 retreats the port door 4 from the advanced position Pf to a retreated position Pb.

A state ST5 indicates a stage in which the port door 4 is lowered to a standby position Pd by the driving mechanism 9. The standby position Pd is a lower limit position of the port door 4 in the opening operation. The standby position Pd corresponds to a lower limit position of the lifting range of the lifting portion 7. When the port door 4 is located at the standby position Pd, the entire opening portion 30 is exposed to the transport space 101.

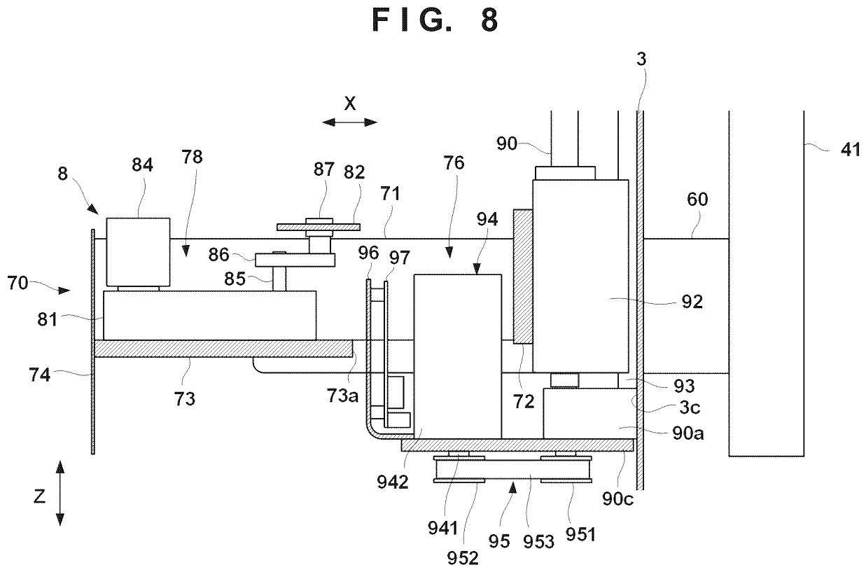

Refer to FIG. 8. At the standby position Pd, the lifting portion 7 overlaps the motor 94 in a side view. In the present embodiment, the lifting portion 7 overlaps the motor 94 as viewed in both the X direction and the Y direction.

Further, in the present embodiment, the driving portion 942 of the motor 94 enters the space portion 76 of the lifting portion 7 at the standby position Pd. In the present embodiment, the lifting portion 7 can be lowered to a position overlapping with the motor 94 in a side view while avoiding interference between the lifting portion 7 and the motor 94. With such a configuration, it is possible to secure a lifting distance required for the port door 4 while reducing the size of the load port 1 in the Z direction. In particular, entire length of the storage portion 5 in the Z direction can be shortened, and the load port 1 can be downsized in the Z direction.

FIG. 8 also illustrates a substrate 97 associated with the motor 94. The substrate 97 is supported by a holder 96. The holder 96 is supported on the upper surface of the attachment member 90c. The substrate 97 includes, for example, a drive circuit of the motor 94 and a sensor circuit of a position sensor. In the example of FIG. 8, not only the motor 94 but also parts of the holder 96 and the substrate 97 are accommodated in the space portion 76. The degree of freedom of arrangement of the holder 96 and the substrate 97 can be improved.

Thus, the opening operation of the container 200 is completed.

Thereafter, the substrate W is taken out by the substrate transport robot 110, the substrate W is processed by a processing apparatus (not illustrated), and the processed substrate W is accommodated in the container main body 201.

Thereafter, a closing operation of the container 200 is performed. The closing operation is performed by a procedure reverse to the procedure illustrated in FIGS. 5 and 6, and the door portion 202 is attached to the container main body 201.

### Second Embodiment

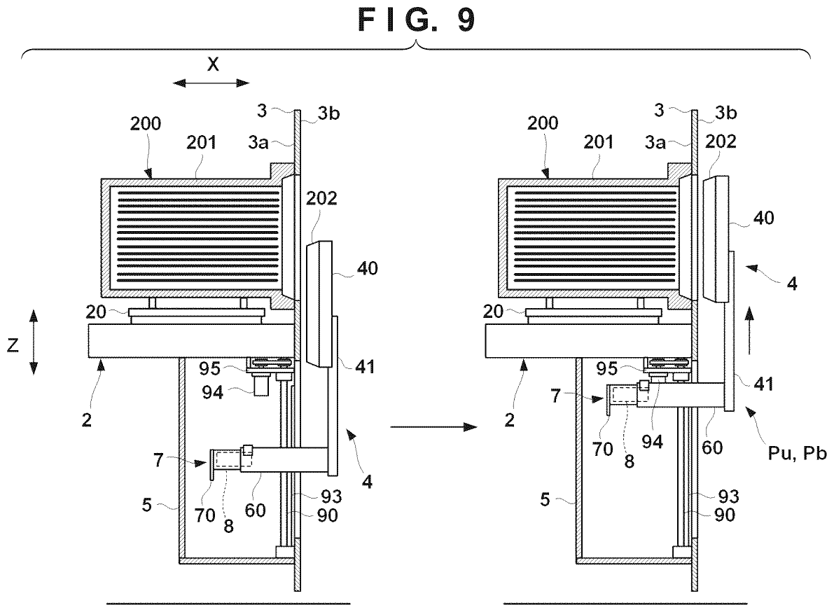

In the first embodiment, the motor 94 is disposed in the lower portion of the storage portion 5, but may be disposed in an upper portion. FIG. 9 illustrates an example thereof. In the illustrated example, the ball screw shaft 90 and the guide member 93 extend from an upper end to a lower end of the storage portion 5. The motor 94 and the belt transmission mechanism 95 are disposed in the upper portion of the storage portion 5. The motor 94 is disposed in the storage portion 5 at the height of the upper end of the guide member 93 in a posture in which the output shaft is directed upward. In the second embodiment, the motor 94 and the belt transmission mechanism 95 are disposed upside down with respect to the arrangement of the first embodiment.

In a case of the present embodiment, the lifting portion 7 overlaps the motor 94 at the attachment and detachment position Pu, and a part of the motor 94 is accommodated in the space portion 76 of the lifting portion 7. Even in such a configuration, it is possible to secure a lifting distance required for the port door 4 while reducing the size of the load port 1 in the Z direction.

While an embodiment has been described, the invention is not limited to the foregoing embodiments, and various variations/changes are possible within the spirit of the invention.

What is claimed is:

1. A load port comprising:
a placing portion on which a container in which a substrate is accommodated is placed;
a storage portion disposed below the placing portion;
a port door configured to be capable of holding a door portion of the container;
a bolts plate disposed between the placing portion and the storage portion, and the port door, the bolts plate including an opening portion which is openable and closable by the port door and through which the substrate is capable of being taken in and out; and
a lifting mechanism configured to move the port door up and down with respect to the opening portion,
wherein the lifting mechanism includes:
a lifting portion stored in the storage portion;
a coupling member configured to couple the lifting portion and the port door through a slit formed in the bolts plate; and
a driving mechanism including a driving source stored in the storage portion and configured to move the lifting portion up and down between a first position and a second position,
the lifting portion includes a space portion into which the driving source is capable of entering at the second position, and
the second position is a position at which the lifting portion overlaps the driving source in a side view, and at which the space portion overlaps the driving source in a plan view.

2. The load port according to claim 1, wherein
the lifting portion includes
an advancing and retreating mechanism configured to advance and retreat the coupling member between a holding position where the port door holds the door portion and a retreating position separated from the holding position, and
a support member configured to support the advancing and retreating mechanism and form the space portion.

3. The load port according to claim 2, wherein
the support member is a frame member including a first side plate and a second side plate, a first end plate coupling the first side plate and the second side plate, and a second end plate separated from the first end plate and coupling the first side plate and the second side plate, and
the space portion is a part of a space surrounded by the frame member.

4. The load port according to claim 3, wherein
the support member includes a bottom plate coupling the first side plate and the second side plate, and
the advancing and retreating mechanism is supported by the bottom plate.

5. The load port according to claim 2, wherein
the advancing and retreating mechanism and the space portion are arranged side by side in a horizontal direction, and
the space portion is located closer to the bolts plate than the advancing and retreating mechanism.

6. The load port according to claim 2, wherein
the coupling member is configured to be slidably supported by the support member.

7. The load port according to claim 3, wherein
the coupling member includes
a first coupling member configured to be slidably supported by the first side plate of the support member and overlap the first side plate in a side view, and
a second coupling member configured to be slidably supported by the second side plate of the support member and overlap the second side plate in a side view.

8. The load port according to claim 1, wherein
the driving mechanism includes a ball screw shaft extending in an up-and-down direction and a ball nut engaged with the ball screw shaft,
the driving source is a motor,
the ball screw shaft is configured to be rotated by driving of the motor, and
the motor is disposed in the storage portion in a posture in which an output shaft of the motor is directed downward.

9. The load port according to claim 1, wherein
the lifting portion includes a support member configured to support the coupling member and form the space portion.

10. The load port according to claim 1, wherein
the first position is an attachment and detachment position corresponding to an upper limit position of a lifting range of the lifting portion, and
the second position is a standby position corresponding to a lower limit position of the lifting range of the lifting portion.

11. The load port according to claim 10, wherein
the port door is configured to expose the entire opening portion when the lifting portion is located at the standby position.

12. A transport system comprising a substrate transport apparatus, and a load port attached to the substrate transport apparatus,
wherein the substrate transport apparatus includes:
a substrate transport robot configured to transport a substrate; and
a housing configured to accommodate the substrate transport robot,
the load port includes:
a placing portion on which a container in which the substrate is accommodated is placed;
a storage portion disposed below the placing portion;
a port door configured to be capable of holding a door portion of the container;
a bolts plate disposed between the placing portion and the storage portion, and the port door, the bolts plate including an opening portion which is openable and closable by the port door and through which the substrate is capable of being taken in and out; and
a lifting mechanism configured to move the port door up and down with respect to the opening portion,
the bolts plate is attached to the housing,
the lifting mechanism includes:
a lifting portion stored in the storage portion;
a coupling member configured to couple the lifting portion and the port door through a slit formed in the bolts plate; and
a driving mechanism including a driving source stored in the storage portion and configured to move the lifting portion up and down between a first position and a second position,
the lifting portion includes a space portion into which the driving source is capable of entering at the second position, and
the second position is a position at which the lifting portion overlaps the driving source in a side view, and at which the space portion overlaps the driving source in a plan view.
